(19) United States
(12) Patent Application Publication
(10) Pub. No.: US 2014/0253848 A1
(43) Pub. Date: Sep. 11, 2014

(54) MULTILAYER IMAGE DISPLAY DEVICE AND METHOD OF OPERATING THE MULTILAYER IMAGE DISPLAY DEVICE

(71) Applicant: BLEXTON MANAGEMENT LTD, NIKOSIA (CY)

(72) Inventor: KLAUS WAMMES, GUNDERSHEIM (DE)

(73) Assignee: BLEXTON MANAGEMENT LTD, NIKOSIA (CY)

(21) Appl. No.: 14/230,547

(22) Filed: Mar. 31, 2014

Related U.S. Application Data
(63) Continuation of application No. PCT/EP2012/004083, filed on Sep. 28, 2012.

(30) Foreign Application Priority Data
Sep. 30, 2011 (DE) 102011114702.4
Jul. 24, 2012 (DE) 102012014645.0

(51) Int. Cl. G02F 1/1335; H05K 5/00

(52) U.S. Cl. CPC G02F 1/133528; H05K 5/0017
USPC 349/96; 361/679.01

(57) ABSTRACT

A multilayer image display device contains at least the following components arranged along a longitudinal extension direction from the rear toward the front in this order: a) a light source, b) a first liquid crystal layer, and c) a second liquid crystal layer. At least one polarization filter is assigned to the first liquid crystal layer and at least one polarization filter is assigned to the second liquid crystal layer. The light from the light source is furthermore guided through at least one optical and/or electro-optical retardation element before it reaches an observer.

### CROSS-REFERENCE TO RELATED APPLICATION

This is a continuation application, under 35 U.S.C. §120, of copending international application No. PCT/EP2012/004083, filed Sep. 28, 2012, which designated the United States; this application also claims the priority, under 35 U.S.C. §119, of German patent application No. DE 10 2011 114 702.4, filed Sep. 30, 2011, and German patent application No. DE 10 2012 014 645.0, filed Jul. 24, 2012; the prior applications are herewith incorporated by reference in their entireties.

### BACKGROUND OF THE INVENTION

### Field of the Invention

The invention relates to a multilayer image display device. It furthermore relates to a method for producing and to a method for operating such an image display device.

Such image display devices, also known as multilayer display systems, are used with preference in videogame consoles for what is known as arcade games (also referred to as arcade machines) and, when used as such, play an active role in increasing the fun factor owing to their 3D-type multi plane image representation. Other, more serious applications are of course also conceivable.

When developing and producing such image display devices, one possible approach is to “design the respective apparatus from scratch” and to optimize the individual components according to the purpose and, if required, to develop new ones. An alternative approach is directed at using, if possible, only commercially available components and to combine them to attain cost advantages in this way. Even in this case maximum image quality, high luminous intensity and a long operating life are the goal, of course.

### SUMMARY OF THE INVENTION

The present invention is therefore based on the object of providing an image display device of the type mentioned, which can be realized by resorting as much as possible to commercially available standard components that exhibit maximum image quality, high luminous intensity, and a long operating life. Furthermore, a corresponding production method and an associated operating method will be provided.

With the foregoing and other objects in view there is provided, in accordance with the invention, a multilayer image display device. The display device contains a component configuration disposed along a longitudinal extent direction from a rear toward a front, the component configuration including and in an order of the rear toward the front: a light source outputting a light, a first liquid-crystal layer, and a second liquid-crystal layer. At least one first polarization filter is assigned to the first liquid-crystal layer. At least one second polarization filter is assigned to the second liquid-crystal layer. At least one optical and/or electro-optical retardation element is provided. Light from the light source is guided through the at least one optical and/or electro-optical retardation element before the light reaches an observer.

The present solution exhibits a substantially more efficient multi-plane display solution, which has the following advantages over the prior art:

1. Substantially less electrical power consumption owing to significantly improved total transmissivity, since the existing polarization of the light between the different liquid-crystal displays is not, as is customary, depolarized using optical films only to be subsequently re-polarized with approximately 50% loss at the first polarization filter of the subsequent liquid-crystal display.
2. Significantly improved readability and wider viewing angle without disturbing artifacts caused by light-absorbing depolarization films or foils that require re-polarization.
3. Significantly improved readability and wider viewing angle regions without disturbing artifacts during image reproduction.

In accordance with an added feature of the invention, the at least one optical and/or electro-optical retardation element is assigned to the at least one second polarization filter. Additionally, the east one optical and/or electro-optical retardation element includes an areal, dimensionally stable and transparent element. Furthermore, the at least one optical and/or electro-optical retardation element includes a signal-processing electronic component. Alternatively, the at least one optical and/or electro-optical retardation element includes an electronic controller which makes possible a propagation time difference or propagation time retardation. Furthermore, the at least one optical and/or electro-optical retardation element satisfies a retardation function f(x).

In accordance with another feature of the invention, the at least one first polarization filter and the first liquid-crystal layer form a first liquid crystal display. The at least one second polarization filter and the second liquid-crystal layer form a second liquid crystal display. An air layer is disposed between the first and second liquid-crystal displays. The air layer is between 1 and 10,000 μm.

In accordance with an additional feature of the invention, the at least one optical and/or electro-optical retardation function f(x) satisfies a necessary condition that a propagation time difference is either equal to 0 or corresponds to a multiple n of wavelength λ.

In accordance with a further feature of the invention, the at least one first polarization filter and the first liquid-crystal layer form a first liquid crystal display. The at least one second polarization filter and the second liquid-crystal layer form a second liquid crystal display. The component configuration is configured such that a background image generated by the first liquid-crystal display is visible through the second liquid-crystal display from the front. The second liquid-crystal display is configured on a drive side for representation of an image which, upon observation, is correctly reproduced from its side which is at the rear in an installation position. A mirroring unit mirrors a foreground image to be represented at an image center line, the mirroring unit is connected upstream of the second liquid-crystal display on the drive side for representation of the foreground image which is correctly reproduced upon observation from the front side.

In accordance with another added feature of the invention, the component configuration is configured such that a background image generated by the first liquid-crystal display is visible through the second liquid-crystal display from the front. At least one of the first and second liquid-crystal displays is optimized in terms of hardware as regards color, brightness and/or contrast for an observation under an inclination angle which differs from zero with respect to a perpendicular on a display surface. A corrector module is connected upstream of the first or second liquid-crystal display on a drive side, the corrector module manipulates an image to be represented prior to transmission to the liquid-crystal display by means of digital image processing such that color, brightness and/or contrast are optimized upon observation of the liquid-crystal display from a perpendicular direction.

In accordance with yet another feature of the invention, no depolarization filter is present between the first liquid-crystal display and the second liquid-crystal display.

In accordance with a yet a further feature of the invention, a first liquid-crystal display is formed of the at least one first polarization filter being a first rear polarization filter, the first liquid-crystal layer being an interposed matrix of liquid crystals, and a first front polarization filter. A second liquid-crystal display is formed of the at least one second polarization filter being a second front polarization filter and, behind the second front polarization filter the second liquid-crystal layer being a matrix of liquid crystals, and the second front polarization filter of the second liquid-crystal display is disposed such that it is rotated in terms of its polarization plane through 90° with respect to the first front polarization filter of the first liquid-crystal display. The first rear polarization filter of the first liquid-crystal display is disposed such that it is rotated in terms of its polarization plane through 90° with respect to the first front polarization filter of the first liquid-crystal display. The second liquid-crystal display has a second rear polarization filter which is aligned, in terms of its polarization plane, equal to the first front polarization filter of the first liquid-crystal display.

With the foregoing and other objects in view there is provided, in accordance with the invention, method for operating a multilayer image display device containing a first liquid-crystal display having a first rear polarization filter, an interposed matrix of liquid crystals, and a first front polarization filter and a second liquid-crystal display having a second front polarization filter and behind the second front polarization filter, a matrix of liquid crystals. The method includes the steps of: generating a foreground image to be represented on the second liquid-crystal display in a positionally correct manner by an associated image computer, being mirrored at an image center line and reproduced in a mirror-inverted manner on the second liquid-crystal display; and reproducing a background image without such mirroring on the first liquid-crystal display.

With the foregoing and other objects in view there is provided, in accordance with the invention, a method for operating a multilayer image display device containing a first liquid-crystal display having a first rear polarization filter, an interposed matrix of liquid crystals, and a first front polarization filter and a second liquid-crystal display having a second front polarization filter and behind the second front polarization filter, a matrix of liquid crystals. The method includes the steps of subjecting an image to be represented on the liquid-crystal displays, using digital image processing, to a preprocessing operation which is of a nature such that a shift of color, brightness and/or contrast resulting from image reproduction and observation from a specific viewing direction is compensated for.

With the foregoing and other objects in view there is further provided, in accordance with the invention, a multilayer image display device. The image display device contains a configuration having a rear display and at least one front display. The configuration is configured such that an image generated by the rear display is visible through the front display, the at least one front display is an emissive display.

In accordance with an added feature of the invention, the at least one front display is an organic light-emitting diode (OLED) display. Wherein the rear display is a non-emissive display through which a light source disposed behind the rear display shines light during operation. Alternatively, the rear display is selected from the group consisting of an LCD display, an emissive display, an organic light-emitting diode (OLED) display, a plasma display and an electroluminescent display.

Other features which are considered as characteristic for the invention are set forth in the appended claims.

Although the invention is illustrated and described herein as embodied in a multilayer image display device and a method, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is an illustration of a two-layer display of conventional construction in section;

FIG. 2 is an illustration of a two-layer display which is significantly improved in terms of its luminous intensity with respect to the variant in FIG. 1;

FIG. 3 is an illustration showing a manufacturing step, indicated in partial perspective illustration, for the production of such a two-layer display;

FIG. 4 is an illustration showing a further, particularly preferred variant of a two-layer display, produced according to FIG. 3, including an associated electronic driving unit;

FIG. 5 is an illustration showing a further variant of a two-layer display according to the invention;

FIG. 6 is an illustration showing an illustrative sketch regarding possible viewing angle regions for liquid-crystal displays;

FIG. 7 is an illustration of a principle sketch relating to a correction of image artifacts that are dependent on the viewing angle and other influences in a liquid-crystal display.

FIG. 8 is an illustration of a two-layer image display device according to a first variant of the invention;

FIG. 9 is an illustration of a two-layer image display device according to a second variant of the invention;

FIG. 10 is an illustration of a three-layer image display device as an example of a further variant of the invention; and

FIG. 11 is an illustration of an image display device according to the invention, in which the respective functional layers are schematically illustrated.

### DETAILED DESCRIPTION OF THE INVENTION

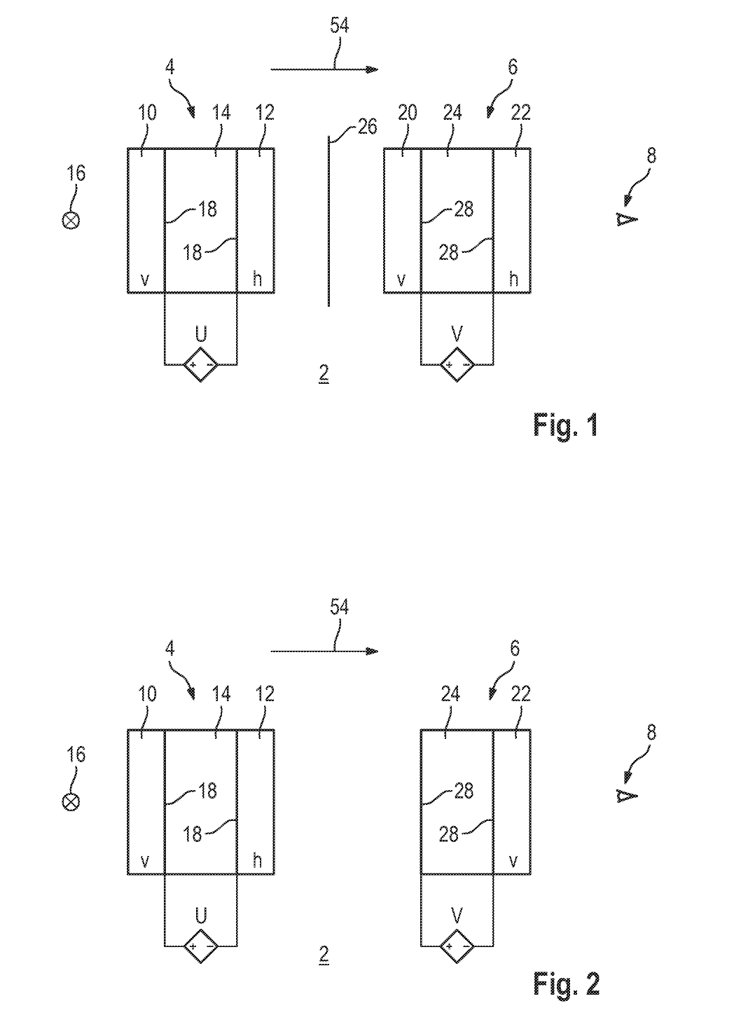

Referring now to the figures of the drawings in detail and first, particularly to FIG. 1 thereof, there is shown a schematic illustration in section a two-layer image display device 2 of known construction, also referred to as a double-layer display or two-plane display, which contains a rear liquid-crystal display 4 (in short LCD) with rectangular image surface and an identically aligned front liquid-crystal display 6 with likewise rectangular image surface having substantially identical dimensions, which are arranged one behind the other such that the image generated by the rear liquid-crystal display 4 shines through the front liquid-crystal display 6 and thus gives an observer 8 the impression of a 3D representation containing two image planes with real parallax effect between background image and foreground image.

For the following description, it was assumed for simplification purposes that the two liquid-crystal displays 4, 6 are arranged one behind the other such that each stands upright on a horizontal base area, with the respective image surface being in the shape of a rectangle whose generally longer edge is parallel to the base area, that is to say horizontal, and whose shorter edge is perpendicular thereto, that is to say aligned vertically, and that the observer views the front liquid-crystal display 6 from the front in a substantially horizontal direction (image representation in wide format similar as in a television device with typical setup). Thus, the expressions “extending horizontally” and “extending vertically” refer to an alignment parallel to the longer outer edge (periphery) and parallel to the shorter edge of the image surface. The expressions should be understood to mean the same thing if the image display device 2 is set up differently in space, which is not only possible, of course, but for certain applications possibly logical.

The rear liquid-crystal display 4 is configured as a color display and is constructed conventionally in the manner of a matrix or of an array of individually electrically drivable liquid-crystal cells, for example of the type twisted nematic (TN) cell. For the purposes of simplifying the drawing, only one individual cell of the type TN is illustrated here. Each individual cell in this case contains a liquid crystal 14 arranged between a rear polarization filter 10 (in short: polarizer) and a front polarization filter 12 (in short: analyzer), with the liquid-crystal molecules in the voltage-free state forming a continuous twist of approximately 90°. The polarization filters 10 and 12 can be formed as flat films, which not only cover an individual cell but the entire array of the liquid crystals 14.

It should already be noted at this point that the TN cell is used here merely to provide a particularly simple and illustrative description, and that the variants of the invention described further below can also be realized with different cell types.

The polarization planes of the two polarization filters 10 and 12 are rotated with respect to one another through 90° such that, in the voltage-free state, the light which is emitted by the light source 16 in the manner of background illumination and is linearly polarized as it passes through the rear polarization filter 10 traverses the liquid crystal 14 with a rotation of the polarization direction and subsequently travels through the front polarization filter 12 without being obstructed. By way of example, the polarization plane of the rear polarization filter 10 is aligned vertically (v) and the polarization plane of the front polarization filter 12 is aligned horizontally (h). By applying an electrical voltage U to the transparent electrodes 18 of the cell, the liquid-crystal molecules of the TN cell (chosen here by way of example) increasingly align parallel to the electric field, resulting in increasing absorption of the light by the front polarization filter 12. The optical transparency of the cell thus continuously diminishes as the voltage U increases; the cell thus becomes darker as the voltage increases (normally white mode).

Alternatively, the reverse function principle could of course also be realized. Typically, the polarization filters are arranged parallel with respect to one another; in that case, without voltage, the cell is dark and becomes transparent only as the voltage increases (normally black mode).

On account of individually drivable sub pixels, which are provided with corresponding color filters for example in the primary colors red, green, blue color representation is made possible in the customary manner.

In the image display device 2 according to FIG. 1, the front liquid-crystal display 6 has the same construction as the rear liquid-crystal display 4, that is to say likewise has a rear polarization filter 20, a front polarization filter 22, and an interposed array of liquid-crystals 24 having transparent electrodes 28 to which the cell voltage V, which is controllable separately for each subpixel, can be applied. The polarization planes of the polarization filters 20 and 22 correspond to those of the polarization filters 10 and 12 in the rear liquid-crystal display 4. Owing to a depolarization filter 26, which is arranged between the rear liquid-crystal display 4 and the front liquid-crystal display 6, is configured as a thin film, and converts incident polarized light into non-polarized light, the front liquid-crystal display 6—and likewise the rear liquid-crystal display 4 illuminated directly by the light source 16—is illuminated with non-polarized light. This construction has the advantage that commercial liquid-crystal displays 4 and 6 can be used without difficulty without requiring any modification. However, the disadvantage is that on account of the polarization filters 12 and 20, which are arranged optically one behind the other, and the interposed depolarization filter 26, a relatively large amount of light is absorbed, as a result of which the image display device 2 is rather faint in terms of light for the observer. If an attempt is made to compensate for this using a light source 16 with a correspondingly high luminous power, this leads to a strong thermal load on the individual optical components and thus also to a relatively short operating life of the image display device 2.

The disadvantages also apply if, instead of an optical component which is expressly provided or adapted as a depolarization filter 26, an optical diffuser is arranged between the two liquid-crystal displays, such as an optically diffuse film which necessarily has a depolarization effect, which is technically/physically unavoidable.

To avoid such disadvantages, the front liquid-crystal display 6 is, in the image display device according to FIG. 2, a color display of in principle identical construction as the rear liquid-crystal display 4, but with the difference that no rear polarization filter and no depolarization filter is provided. In particular, it may be a liquid-crystal display 6 which is structurally identical to the rear liquid-crystal display 4, with the rear polarization filter removed. The alignment of the rows and columns of liquid-crystal cells and the voltage-less alignment of the liquid-crystal molecules in the liquid crystal 24 between the substrate plates of the respective cell are accordingly selected to be identical in principle as in the rear liquid-crystal display 4, which has a similar construction to that according to FIG. 1. The alignment of the front polarization filter 22 is here rotated in terms of its polarization plane through 90° with respect to the front polarization filter 12 of the rear liquid-crystal display 4, is thus selected in the present example to be vertical (v). This means that the light emerging from the front polarization filter 12 in the rear liquid-crystal display 4 is already polarized—in the present example with a horizontal (h) polarization plane—and in this state enters the respective liquid crystal 24 of the front liquid-crystal display 6 directly, without having to previously pass again through a polarization filter and/or depolarization filter. The polarized light entering the liquid crystal 24 of the front liquid-crystal display 6 is here rotated further as regards its polarization direction in accordance with the voltage V applied to the cell, and its polarization component which is in the direction of passage exits the front liquid-crystal display 6 through the front polarization filter 22, which acts as the analyzer, in the direction toward the observer 8.

In order to obtain an image representation which is not inverted or chromatically distorted with the same installation position of the front liquid-crystal display 6 and the rear liquid-crystal display 4, the polarization plane of the front polarization filter 22 of the front liquid-crystal display 6 is thus arranged such that it is rotated through 90° with respect to the front polarization filter 12 of the rear liquid-crystal display 4. In commercial liquid-crystal displays of identical construction, which are available as ready-to-install and units that are ready for operation, this could be done for example by removing the front polarization filter 22, which is initially mounted in the “wrong” alignment, from the matrix of the liquid-crystals 24 of the front liquid-crystal display 6 and subsequently remounting a polarization filter of fitting dimensions and with a polarization plane that is rotated through 90°. However, this would be relatively complicated, especially because—as described above—the rear polarization filter would also have to be removed.

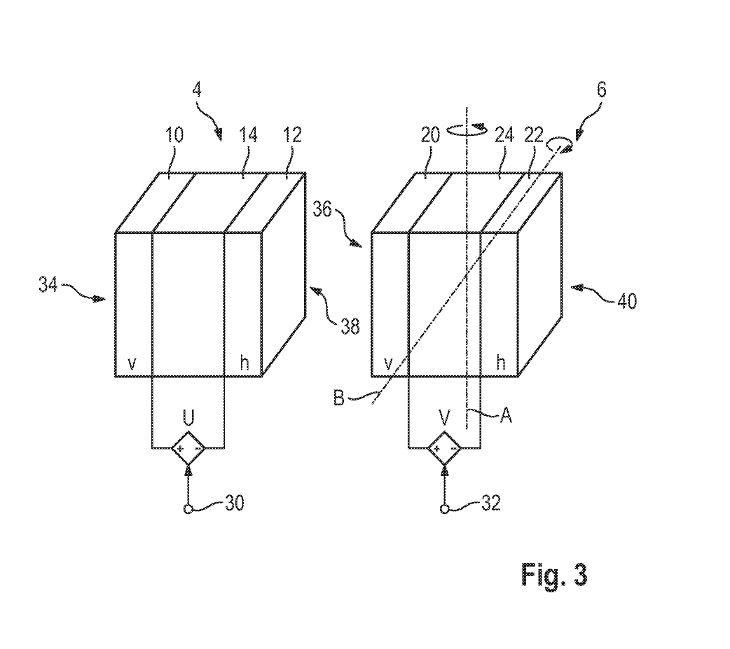

To simplify the construction, the production method illustrated in FIG. 3 is used: in a first step, two commercial liquid-crystal displays 4 and 6 of substantially identical construction and with generally rectangular image surface and with identical configuration of polarization filters 10, 12 and 20, 22 and liquid-crystals 14, 24 are provided. Each of the two liquid-crystal displays 4 and 6 thus has a rear, that is to say rearward facing polarization filter 10 and 20 with, for example, vertical (v) polarization plane, and a front, that is to say front-side polarization filter 12 and 22 with a polarization plane that is rotated through 90°, in the present example is thus horizontal (h), between which in each case a matrix of liquid-crystals 14 and 24 is arranged, which are driven in identical manner via a respectively associated interface 30 and 32 or are connectable to an associated image computer. Each of the two interfaces 30 and 32 is thus configured for image representation in which the liquid-crystal display 4 and 6 is illuminated from the rear side 34 and 36, and the generated image is viewed from the front side 38 and 40.

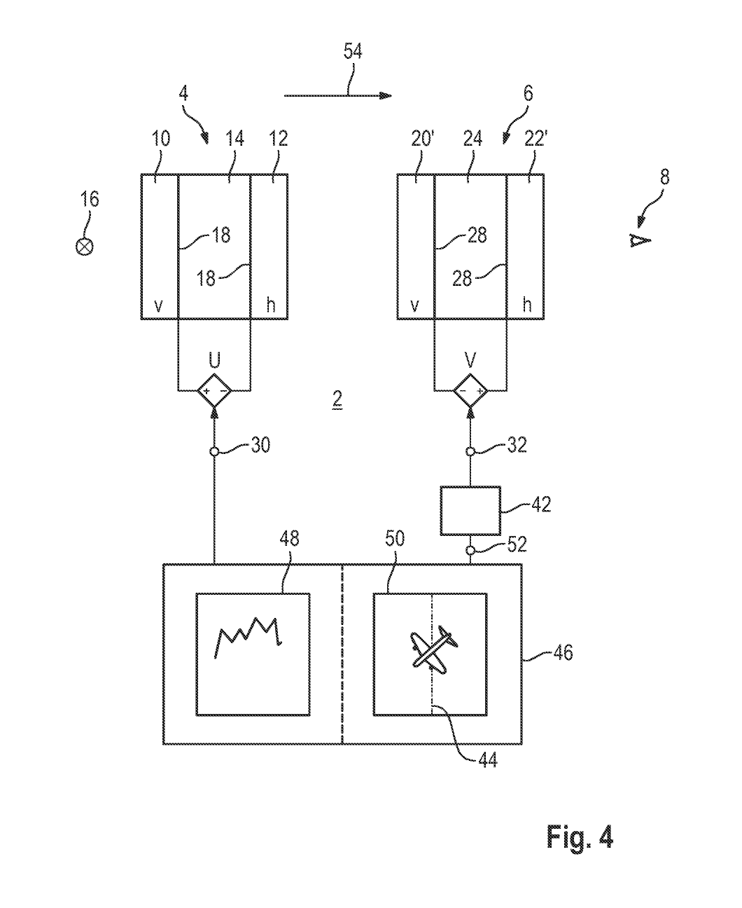

The liquid-crystal display 6, which is at the front in the image display device 2 to be produced, is now aligned in a second step such that the rear polarization filter 20 becomes the front polarization filter 22′, and, conversely, the front polarization filter 22 becomes the rear polarization filter 20′ (see FIG. 4). As compared to the alignment illustrated in FIG. 3, the total front liquid-crystal display 6 is thus rotated for example through 180° about its vertical axis A. Alternatively, a 180° rotation about the horizontal axis B is also possible. The now front polarization filter 22′ of the front liquid-crystal display 6 therefore has the same polarization plane, in the present example a vertical (v) polarization plane, as the rear polarization filter 10 of the rear liquid-crystal display 4, while the now rear polarization filter 20′ of the front liquid-crystal display 6 has the same polarization plane, in the present example a horizontal (h) polarization plane, as the front polarization filter 12, located directly opposite, of the rear liquid-crystal display 4. The overall result is the configuration illustrated in FIG. 4.

Both steps mentioned here can of course be realized in a single pass; the mental division in the present case is thus of a purely illustrative nature.

Subsequently or beforehand, the now rear polarization filter 20′, which in the present example is equipped with a horizontal polarization plane, of the front liquid-crystal display 6 could be removed, such that the configuration known from FIG. 2 comes about directly—except for the polarity of the electrodes 28. However, this is not necessary since the light incident on the polarization filter 20′ is already suitably aligned or polarized in the passage direction owing to the identically aligned upstream polarization filter 12, and therefore its intensity when passing through the polarization filter 20′ is practically not attenuated further. In that regard—seen from a functional point of view—the two polarization filters 12 and 20′ could also be considered a single polarization filter. In terms of production technology, it is of course advantageous if the polarization filter 20′ is not removed, since the setup of the image display device 2 can in that case take place merely by resorting to unmodified, commercial displays. Alternatively, it may still be removed if required (or not be present from the beginning) in order to minimize the transmission losses and imaging artifacts, which are unavoidable in reality during passage through the filter and occur even with “appropriate” alignment with respect to the polarization plane of the incoming light.

However, by swapping the front side and rear side, the positions of the respective image information on the front liquid-crystal display 6 are mirrored relative to the position on the rear liquid-crystal display 4 since the front liquid-crystal display 6 was originally intended and, on the drive side, adapted for being observed from what was initially the front side 40 according to FIG. 3, which however has now become the rearward side according to FIG. 4. The image information must therefore likewise be represented in a mirrored fashion using suitable drive electronics in order to obtain a correspondingly non-falsified representation. This is achieved by way of an electronic mirroring unit 42, which can be implemented as specialized hardware, but possibly also in form of software running on a universal or special computer and which carries out mirroring of the image content to be represented of the front liquid-crystal display 6 either on the vertical or on the horizontal image center line 44 (i.e. axial mirroring at the perpendicular bisector of the corresponding outer image edge), depending on its installation position. The mirroring unit 42 can to this end for example be a constituent part of a separate image computer or an upstream connected module, which is connected on the data side to the front liquid-crystal display 6 via the commercial, unmodified interface 32. Alternatively, drive electronics having a corresponding mirroring routine could of course also be addressed, which drive electronics is connected downstream of the interface 32 and integrated in the liquid-crystal display 6, if already installed at the factory.

In the embodiment variant according to FIG. 4, for example a common image computer 46 is provided, which calculates both the background image 48 (in the present case for example a mountain landscape) to be represented on the rear liquid-crystal display 4 and the foreground image 50 (in the present case for example an aircraft) to be represented on the front liquid-crystal display 6 with pixel accuracy. For this purpose, of course two separate image computers may also be provided. While the background image 48 is fed directly, i.e. in a positionally correct manner, to the interface 30 of the rear liquid-crystal display 4 and is displayed on the latter without any change in representation, the foreground image 50 is previously mirrored in the mirroring unit 42 at the vertical image center line 44, as an alternative to the horizontal image center line (according to the vertical or horizontal display center line of the front liquid-crystal display 6) in order to make possible, as a result, the non-falsified, positionally correct representation of both image planes that is desired for the observer 8.

The mirroring unit 42 can be a constituent part of the image display device 2 in the mounted, ready-to-sell state, which is then addressed by the user via the standard interface 30 and the interface 52 which is extended by the mirroring function.

The setup described can be generalized to more than two layers of liquid-crystal displays, by suitably aligning and mounting, starting from the basic setup illustrated in FIG. 4, successive further liquid-crystal displays in front of the front liquid-crystal display 6, that is to say in the direction toward the observer 8. A third liquid-crystal display to be mounted in front of the liquid-crystal display 6 which is at the front in FIG. 4 would in that case for example have to be aligned again like the rear liquid-crystal display 4, such that no image mirroring would be necessary for the third layer or image plane. On the other hand, mirroring would be necessary for a fourth layer. The basic principle of such multilayer image display device (multilayer display) is that the mutually facing polarization filters of liquid-crystal displays which are directly following one another are aligned in the same manner as regards their polarization planes, and that the polarization planes of the polarization filters located on the respectively other side are rotated with respect thereto through 90°. For the second, fourth etc. image plane, in each case image mirroring of the type described above is then necessary, while this is not necessary for the first, third etc. image plane.

The description has so far related by way of example to liquid-crystal displays of the “normally white” type with corresponding configuration and alignment of liquid-crystals and polarization filters. However, the described principles can similarly also be transferred to different configurations, for example if liquid-crystal displays of the “normally black” type are used. In that case, an image computer of the described type can generally be used to achieve, in the case of an installation position of a liquid-crystal display which is “wrong” with respect to the drive-side setup, an inversion or mirroring of the image content, and thus as a result a non-falsified and positionally correct image reproduction.

In the concept which is realized in the present case of a multilayer display, it must be ensured that a subpixel, provided with a specific color filter, of the front liquid-crystal display 6 is illuminated in a primarily diffuse manner by way of the entire rear liquid-crystal display 4, i.e. obtains illumination contributions from each subpixel of the rear liquid-crystal display 4 which are, according to the geometric beam profile, more or less strongly attenuated. Owing to the variably strong dispersion of the light beams impinging on the respective subpixel of the front liquid-crystal display 6 at various angles, in the normal case it is ensured that sufficiently “white” light with the desired spectral component arrives, even if a primarily uniform background image with a specific primary color is represented on the rear liquid-crystal display 4.

Such effects can be modeled physically in a comparatively simple manner and be taken into account in the color control of the two displays: in particular objects or structures, represented on the rear liquid-crystal display 4, can be reproduced here in false-color representation or negative representation, as it were, which is compensated for as regards the observer 8 by a complementary primary coloring of the front liquid-crystal display 6. For such optimization, in which for example a particularly large overall brightness or a particularly high contrast for one or both image planes can be aimed at, a suitably configured image computer or the like may again be provided.

It is likewise expedient to improve the spectral mixing of the light incident on the front liquid-crystal display 6 by way of additional measures which are further described below.

With the interaction of two or more pixel- or image point-oriented liquid-crystal displays 4 and 6, owing to the geometric pixel or raster structure, optical artifacts and aberrations such as Moiré or the like can occur. Since the artifacts in the present case are formed in and with pre-polarized light, the effects of the phenomena can be reduced or suppressed more simply as if they were formed with non-polarized light. The phenomena represent optically mainly intensity patterns or spectrally spread refraction and/or diffraction patterns which are distributed spatially and/or areally. The phenomena are normally added to the desired optical representation and falsify the latter. However, since they develop here in and/or with polarized light and, in the further optical path, again only polarized light of specific vibration planes can be used, and this light which is to be used further is intended to have a spectral composition, which is as complete as possible, for representation of all colors, and additionally as little light as possible is intended to be lost over the entire optical path, it is advantageous to treat the mentioned phenomena such that the effects of the color and intensity patterns which are distributed in a spatial and/or areal manner are combined, summed and then selectively sorted in a suitable fashion.

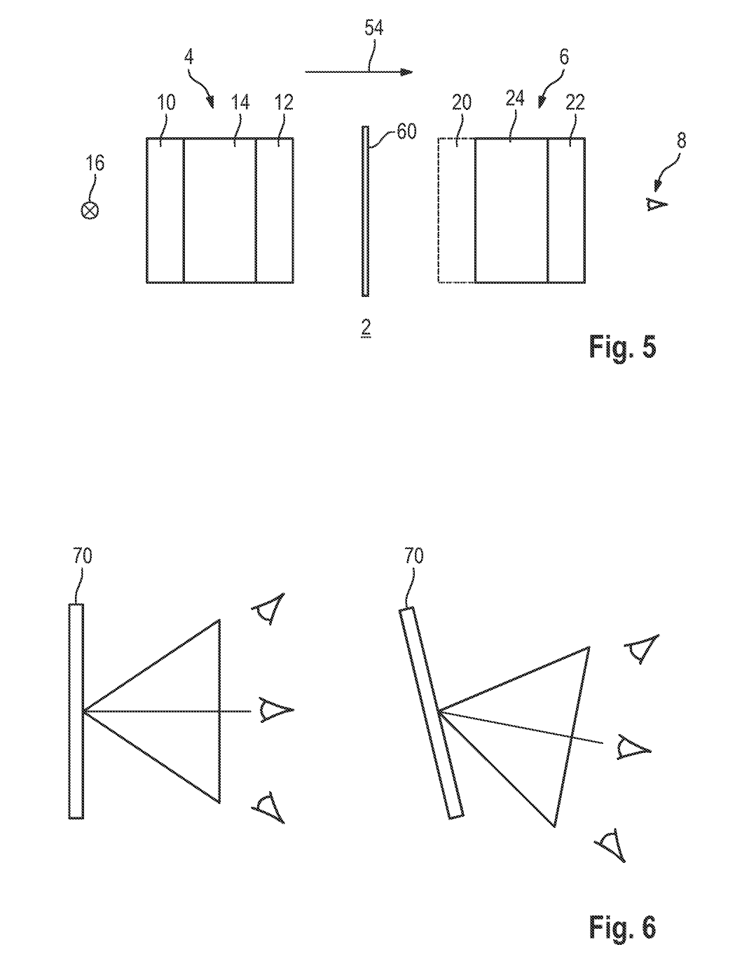

This is done by inserting an active, reflective polarizer 60 between the rear liquid-crystal display 4 and the front liquid-crystal display 6, as illustrated in FIG. 5 by way of example. Such an active, reflective (non-absorbing) polarizer is known for example from U.S. Pat. No. 5,422,756, whose content of disclosure is hereby declared part of this document. Alternatively or additionally, similar advantageous effects based on multiple reflections of light beams at the Brewster angle relative to the boundary layer can be achieved by a suitable configuration and material selection for the optical boundary surfaces of the two liquid-crystal displays 4, 6 which are arranged one behind the other, as described below for the reflective polarizers of the compact film-type.

The effect of the setup of the active, reflective polarizers 60 is that only light in the predetermined polarization direction relative to the front polarization filter 22 of the liquid-crystal display 6 can be transmitted, depending on the representation mode used, “normally black mode” or “normally white mode.” For the “normally black mode”, preferably both the active reflective polarizer 60 and the front polarization filter 22 of the liquid-crystal display 6 have the same polarization alignment. For the “normally white mode,” expediently both have an unequal polarization alignment which is typically rotated through 90°. The construction of the inserted active, reflective polarizer 60 first lets through light of the polarization plane that is predetermined by the corresponding positioning of the component while simultaneously reflecting back light which cannot directly travel through the predetermined polarization plane in various layers of the component. The back-reflection occurs, depending on the given, already existing polarization, at various boundary layers within the inserted active, reflective polarizer 60. Additionally, each reflected light component additionally experiences, in dependence on at which plane it was reflected, a further incremental optical rotation of the polarization plane per plane passed.

The result is the following effects now described.

Owing to the multiple back-reflection of light of “non-appropriate” polarization at various layers within the volume of the active, reflective polarizer 60 with corresponding dispersion and diffusion at the boundary surfaces and the associated distribution at various solid angles and back again into the interspace between the rear liquid-crystal display 4 and the front liquid-crystal display 6, and the combination and summing of all components taking place there before the light then takes another “run” through the active, reflective polarizer 60, homogenization of the above-described optical phenomena and elimination or at least a reduction of the spatially and/or a really distributed intensity patterns and/or spectrally spread refraction and/or diffraction patterns is achieved.

Owing to the described multiple back-reflections including the dispersion and diffusion which are necessarily associated therewith, for the observation of the front liquid-crystal display 6 this results in a considerably improved back-illumination and, with respect to the local spectral distribution, a better spectral completeness, that is to say “more mixed” and thus “whiter” light. A further result is a higher local brightness and thus a higher total brightness and better color representation on the surface of the front liquid-crystal display 6, because ultimately each sub pixel of the front liquid-crystal display 6 receives illumination contributions from each sub pixel of the rear liquid-crystal display 4, which contributions are more or less pronounced according to the geometric beam profile.

The above-described concept is illustrated by way of example in FIG. 5: the active, reflective polarizer 60 is arranged in the optical path between the rear liquid-crystal display 4 and the front liquid-crystal display 6. The rear liquid-crystal display 4 has a rear polarization filter 10 and a front polarization filter 12. The front liquid-crystal display 6 has, if present, a rear polarization filter 20, which may also have been removed or not have been present from the start and is therefore shown in FIG. 5 by way of dashed lines, and a front polarization filter 22. The voltage supply to the electrodes associated with the liquid-crystals 14 and 24 is here not shown for simplification purposes. The front polarization filter 12 of the rear liquid-crystal display 4, the active polarizer 60, and, if present, the rear polarization filter 20 of the front liquid-crystal display 6 are matched to one another as regards their polarization planes, that is to say generally aligned identically, in a manner such that light which is incident from behind on the front polarization filter 12 of the rear liquid-crystal display 4, and which in terms of polarization is in passage alignment and thus passes through the polarization filter 12 without significant attenuation, can also pass through the following active, reflective polarizer 60 and, if present, the rear polarization filter 20 of the front liquid-crystal display 6 without significant attenuation.

For the purposes of understanding the above-described effects and advantages of the active, reflective polarizer 60, it should be taken into account, however, that in reality no polarization filter has ideal optical properties. Rather, depending on the quality of the respective polarization filter, a more or less large portion of the light exiting it has a polarization plane which deviates to a greater or lesser extent from the desired (preferred) polarization plane. That is to say in particular that the light exiting the front polarization filter 12 of the rear liquid-crystal display 4 in practice has certainly noteworthy portions whose polarization plane is more or less strongly rotated with respect to the actually set polarization plane. It is these portions which are actually normally undesired and ultimately disregarded that are converted in the above-described manner using the active, reflective polarizer 60 into light used for the back-illumination of the front liquid-crystal display 6.

In a non-illustrated deviation from FIG. 5, additionally or alternatively to the active, reflective polarizer 60 arranged between the liquid-crystal displays 4 and 6, one or more of the usually conventional polarization filters 10, 12, 20, 22 can be configured as active, reflective polarizers of the previously described type.

A further aspect which is directed at rendering purchasable standard components usable for production of a high-quality multilayer display and which can be combined with the previously explained aspects is now described.

Owing to typical application of purchasable liquid-crystal displays for example as display devices of portable computers such as notebooks and netbooks, the liquid-crystal displays are matched in terms of their cell voltage transmission characteristic (gamma characteristic) such that the best contrast with the least amount of color shift is not aligned as an angle bisector of the usable viewing angle region orthogonally centrically with respect to the display surface. Rather, the gamma characteristic is set to have a corresponding shift owing to the preferred observation direction obliquely from below.

The geometric situation is illustrated in FIG. 6. The left-hand image half illustrates a symmetrically designed LCD display 70. A satisfactory image quality is achieved upon viewing with a viewing angle within the marked region. Outside the region, color shifts, reduced contrast and reduced brightness become noticeable in a very disturbing manner. The best viewing angle comes about when observing in the direction of the angle bisector of the defined angle region, that is to say in the direction perpendicular to the (planar) display surface. In the case of the LCD displays, which are typically provided for use in notebooks and are available at comparatively low cost owing to manufacture in particularly large numbers, the best viewing angle, on the other hand, is tilted with respect to the orthogonal at an angle of for example 20 to 50°, which is shown in the right-hand image half. As already explained, this is achieved among others by a gamma characteristic which is shifted with respect to the symmetric design and implemented in the driving hardware.

However, the shifted gamma characteristic is extremely disturbing when used in 3D-suitable multilayer displays, since, owing to the various positions, polarization planes and transfer functions, which are dependent on the viewing angle, in the involved liquid-crystal cells, polarizers and the maximum available or usable viewing angles which are produced overall, the functionality with respect to contrast, color representation, optical artifacts and overall brightness of the overall system is thus considerably restricted.

In order to avoid this, provision is made according to the invention for the resulting gamma characteristic to be set again such that the shift required for the initial function in notebooks is compensated for or reversed. This can be achieved in principle by way of at least two methods: first, via a modification of the individual used liquid-crystal displays individually, which is correspondingly complicated and costly. Or by way of suitable manipulation of the display drive data—similar to a controlled predistortion, as is known from audio data transmission, to equalize transmission characteristics—without individual modification of the individual used liquid-crystal displays. Since the liquid-crystal displays used are digital assemblies whose display information is supplied by time-sequential data streams which then control each individual image point successively, they can also be used to represent an image-point-accurate manipulation of the display data and thus also to carry out an image-point-accurate associated correction of the gamma characteristic. In this way it is possible not only to realize the correction of the gamma characteristic, but also to carry out, or at least significantly simplify, a compensation for all components located in the optical path—such as the polarizers—and of the optical artifacts caused thereby. The correction described here is advantageous in particular for multilayer displays having more than two planes and for use of the above-mentioned widely available, inexpensive notebook liquid-crystal displays in order to be able to achieve acceptable optical results.

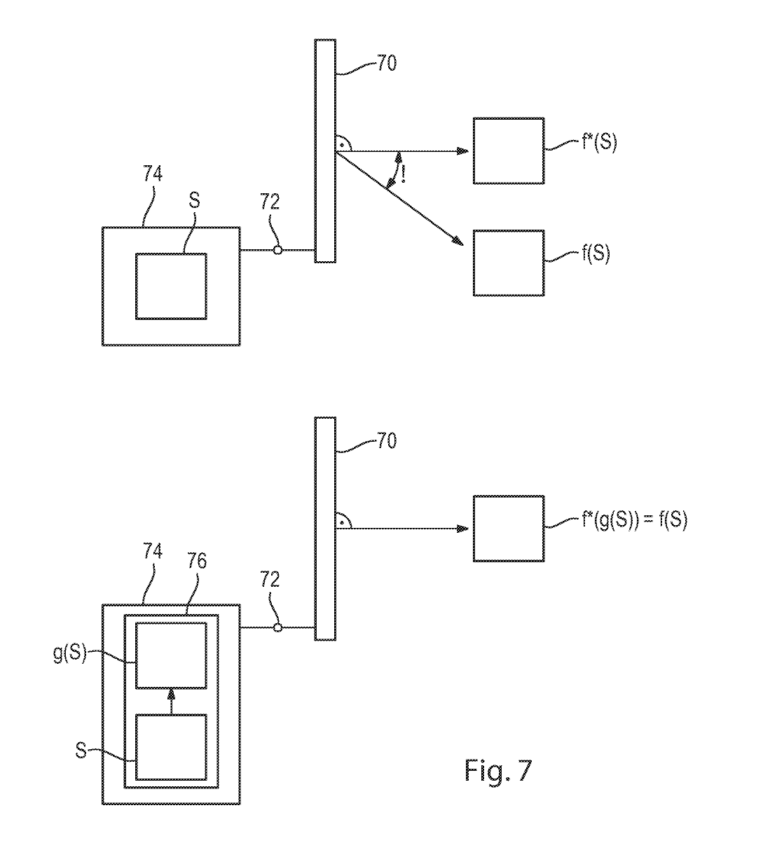

The situation is illustrated in FIG. 7: the top image half illustrates an LCD display 70 which is connected via an interface 72 to an associated image computer 74 and is driven thereby. An original image S stored in the image computer 74 in digital form is displayed on the LCD display 70 such that an observer 8 sees an image f(S) which is optimized in terms of its physiological perception when the display surface is observed under an inclination angle with respect to the orthogonal. When viewed in the direction of the orthogonal, however, the observer perceives an image r(S) which is, as it were, “distorted” as regards color, brightness, contrast and possibly further optical parameters. In order to eliminate the disturbing influence and make possible non-falsified observation from a perpendicular direction, an image computer 74, in the extension illustrated in the bottom image half, is equipped with a corrector module 76 which maps the original image S onto an image g(S) initially with application of an appropriate mapping rule, which image is then fed via the interface 72 to the LCD display for display. The mapping rule S→g(S) is of a nature such that the image f*(g(S)) perceived by the observer 8 when viewing from the perpendicular viewing direction corresponds as far as possible in terms of color, brightness and contrast to the image f(S) which is originally visible under the viewing angle α—without the inclusion of the corrector module 76—that is to say f*(g(S))=f(S).

As a result, by using suitable “predistortion” in the electronic image processing, the later “distortion” in the image reproduction is countered, as it were. The mapping rule S→g(S) which is necessary there for and is dependent on the inclination angle α can, for example, be obtained by determining and inverting the function f(S) and/or f*(S) and possibly further functional relationships. This can be done, for example, with the use of physical-mathematical models in an approximately analytical or even empirical manner by comparison of corresponding measurement data under different inclination angles α. Moreover, as already mentioned above, other image artifacts, which are caused by different components in the optical path (such as the polarization filters), can also be compensated for in this way. The mapping rule used for the predistortion or, more generally, preprocessing can here be used in the corrector module 76 conventionally in the manner of a local or global digital filter or as a combination of a plurality of such filters. Advantageously, this technique is applied to each of the liquid-crystal displays, which are arranged one behind the other, of a multilayer display.

Further advantageous aspects of the invention relate to the use of self-luminous, emissive displays in multilayer configurations, among others in combination with the purely transmissive displays described so far, for example of the LCD type. A specific embodiment and configuration of the present invention is in this context directed to the use of OLEDs (organic light-emitting diode) in displays for improving the 3D effect.

A combination of the embodiments of the present invention described below with all or specific features of the previously described embodiments results in an amplification of the individual effects and of the overall effect and is expressly a constituent part of the present invention. It is particularly advantageous if the emissive display layers are also used and possibly combined with other layers such that polarized light is “processed” if possible over the entire optical path of the 3D image display device and depolarization, for example by way of optical diffusion, is avoided as far as possible.

If the front display itself emits light, i.e. does not rely on background illumination to generate images, but is still optically transparent (i.e. see-through)—especially in the wavelength range of visible light—such that the image generated by the rear display is still perceivable, completely new possibilities of two-layer or multilayer image representation and the associated electronic driving arise. In particular it is then possible for a bright foreground object to be represented on the front display plane, even if the background image on the rear display plane is completely dark across the entire display extent. The same is true for the color representation, when the front display is capable of emitting color light, that is to say for example when reproducing a foreground object which is luminous in an intense green color in front of a background image which is of an intense red color.

In a particularly advantageous configuration, the front display is an OLED display, that is to say is based on the technology of organic light-emitting diodes (OLEDs) which are produced in particular as thin film elements using organic semi conductive materials and which are combined in the manner of a matrix to form a display with individually drivable pixels. Such displays have comparatively fast reaction times and, due to their high energy efficiency, generate only relatively little waste heat during operation.

As the encapsulation of the image unit cells improves, a high operating life of the OLEDs with few ageing symptoms is expected in future. Above all, it is already possible to manufacture OLED layers which are transparent to a high degree and consequently also to manufacture displays which—at least in the non-emitting state—attenuate light shining through from the rear only slightly in terms of its intensity. It is especially this property which in other contexts may be disturbing which is advantageous in the front layers of a multilayer display, since the background image need have only a comparatively low brightness and is still perceivable effectively through the front display.

Possible alternatives to OLED displays according to the invention are LED displays, plasma displays (PDPs), field emission displays (FEDs), electroluminescent displays (ELs) and surface-conduction electron emitter displays (SEDs), as long as these are configured and manufactured to be correspondingly transparent.

Even if the emitting unit cells of these display types do not have the desired optical transparency, it is possible—if a correspondingly lower pixel density and a correspondingly lower resolution are accepted—to provide comparatively highly transparent interspaces of suitable extent between the unit cells such that overall a relatively large amount of light from the rear display layer can pass through the front display layer of such design and the background image as such remains perceivable. In addition or alternatively, suitably configured apertures (free openings) can be provided in the respective display of the front layers, such as for example in the form of pixel-free regions or the like of areal extent.

Furthermore, with the aid of suitable optical devices such as for example lenses, prism and/or mirror systems, light deflection around opaque display regions of the front display layer(s) may be provided such that the light components which are blocked without such measures can still be used.

In one possible variant of the present invention, the rear display is a non-emissive display through which a light source arranged behind it shines light during operation. This can be in particular a liquid-crystal display (LCD) or a thin-film transistor display (TFT) with LED background illumination (LED backlight). Advantageously, however, a plasma-based light source on the basis of exciplex excitation is used in order to achieve a corresponding light distribution, luminous density, spectral completeness and efficiency. Exciplexes are in particular metastable aggregates or complexes of two or more atoms or molecules, in particular with unequal partners. Alternatively, for example, cold cathode tubes, electroluminescent films or other luminous means can be used for background illumination. A further variant of the present invention is the illumination which has become known as edge light, which originates from the display periphery and is distributed into the surface, if appropriate, via optical waveguides.

In one alternative variant, the rear display is likewise an emissive display, in particular an OLED display or a plasma display or an EL display.

It is comprised by the meaning of the invention and the wording of the claims to provide an image display device having three or more layers of displays which are arranged one behind another, wherein at least one of the displays arranged in front of the rearmost display is an emissive display in the sense mentioned above.

Advantageously, this applies to all displays arranged in front of the rearmost display and possibly even to the rearmost display. However, it is for example also possible to arrange emissive and non-emissive displays in alternating manner or to choose other combinations and orders.

In one modification of the basic idea, one of the displays which is located farther toward the rear could emit, in place of/in addition to visible light, light in a wavelength range outside the visible spectrum, which is at least partially transmitted by a display located in front of it and in the process is converted into visible light.

The advantages achieved with the invention are in particular that owing to the self-luminous and simultaneously primarily transparent configuration of at least one of the front displays in a multilayer display, basic limitations of existing LCD systems are eliminated and new possibilities for extremely luminous, contrast-rich and color-intensive 3D representations with parallax effect are created, without a need for particularly bright separate light sources for background illumination.

What displays of such technologies have in common is that, when used as front displays, they must be at least partially transmissive at least partially for the image information of the rear displays—for example by corresponding transparency, partial aperture or aperture pattern, or by means of suitable optical devices such as for example lens, prism and/or mirror systems. When more than two layers are used, an actually volumetric image representation is achievable in which each observer receives different image information from various angles simultaneously in dependence on the observation angle without further aids such as optical barriers, (shutter) glasses, polarization filters, eye tracking or the like, the depth resolution of which is primarily dependent on the number of the display layers used.

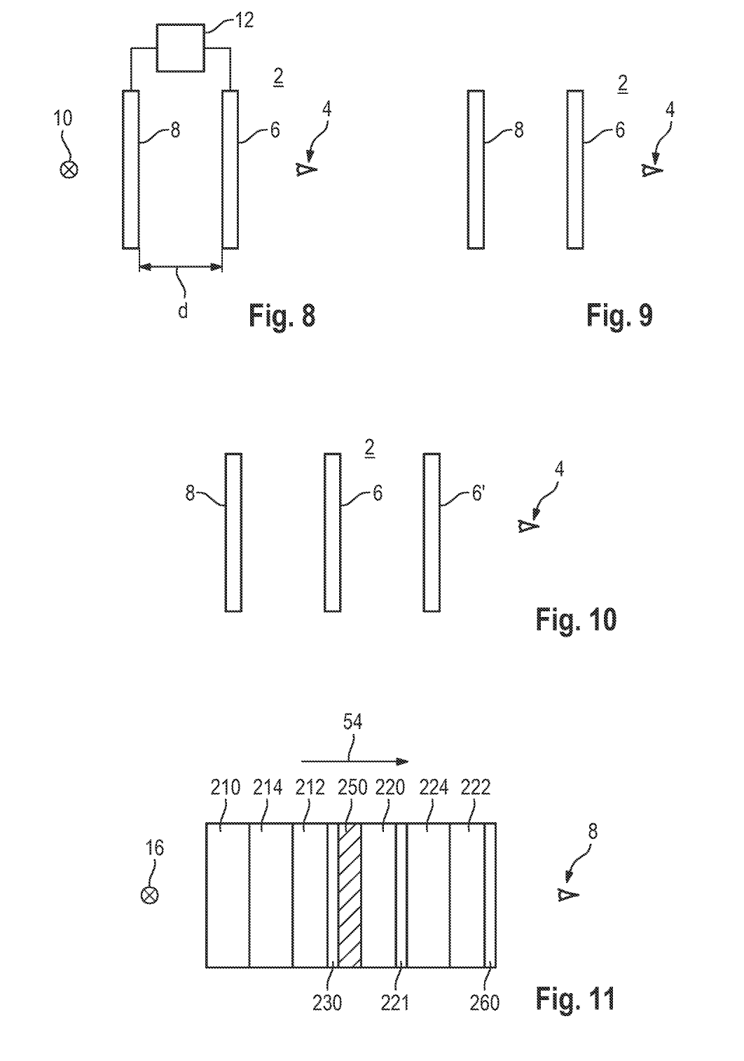

The two-layer image display device 102, which is illustrated in FIG. 8 in cross section, has, seen in the viewing direction of the observer 104, a front display 106 and a rear display 108 having substantially identical dimensions, which are arranged at a distance d one behind the another. The two displays 106, 108 are arranged one behind the other to be aligned such that the background image generated by the rear display 108 is visible for the observer 104 through the front display 106. Foreground images or foreground objects represented on the front display 106 are here located practically over or in front of the background image such that—certainly in the case of moving motives—the impression of a 3D representation with spatial depth and with parallax effect is produced.

In the variant illustrated in FIG. 8, the rear display 108 is an LCD display which is illuminated by a light source 110 which is arranged behind it, for example in the form of an LED panel, but preferably via a plasma light source which is based on exciplex excitation. The rear display 108 is thus not self-luminous but provides, as it were, an array of individually drivable color filters which transmit a greater or smaller amount of light of a corresponding color from the light source 110 in a direction toward the observer 104, as a result of which, with sufficient observation distance, the desired image impression results in a known manner. The front display 106, on the other hand, is designed as a self-luminous, optically transparent OLED display having an array of individually drivable organic light-emitting diodes having a suitable emission wavelength, that is to say color. It is therefore not necessary for the generation of the foreground image for the rear display 108 to transmit light from the light source 110. Rather, the background image may also be completely dark. However, if a background image of corresponding brightness is present, it is visible through the front display 106 owing to its optical transparency, and is the more perceivable the smaller the local emission efficiency is there. With a suitable preparation of the foreground image and of the background image in an image computer 112 which is connected upstream of the two displays 106, 108 and can be part of the image display device 102 or can be separate therefrom, complex 3D scenarios can thus be represented.

The variant illustrated in FIG. 9 differs from that in FIG. 8 in that the rear display 108 itself is an emissive display, for example an OLED display or a plasma display. A separate light source for background illumination is therefore not necessary. The image computer 112 is omitted in this illustration.

FIG. 10 illustrates as a further example a three-layer image display device 102 having a rear display 108 and two displays 106, 106′ located in front of it, wherein at least one of the two front displays 106, 106′ is an optically transparent, self-luminous display in the sense mentioned above. In particular, both front displays 106, 106′ can be transparent and self-luminous.

It is also possible of course for further display layers to be provided.

A combination of the embodiments described below of the present invention with all or specific features of the embodiments described above results in an amplification of the individual effects and of the overall effect and is expressly a constituent part of the present invention.

In one further preferred embodiment of the present invention, the multilayer image display device according to the invention has at least the following components which are arranged along a longitudinal extent direction from the rear toward the front in this order: a light source, a first liquid-crystal layer, a second liquid-crystal layer, wherein the first liquid-crystal layer is assigned at least one polarization filter and the second liquid-crystal layer is assigned at least one polarization filter, wherein the light from the light source is furthermore guided through at least one optical and/or electro-optical retardation element before it reaches an observer 8.

The at least one optical and/or electro-optical retardation element is advantageously assigned to at least one polarization filter and satisfies a retardation function f(x), which satisfies the necessary condition that the propagation time difference is either equal to 0 or corresponds to an integer multiple n of the wavelength λ, i.e. n*λ.

Advantageously, the retardation element consists of an areal, dimensionally stable and transparent element, for example a film.

Advantageously, the retardation element consists of a signal-processing electronic component.

Advantageously, the retardation element consists of an electronic controller which makes possible retardation of the propagation time through the retardation element.

Advantageously, an air layer is provided between the first and the second liquid-crystal display, which air layer is between 1 and 10,000 μm.

Four preferred embodiments of the present invention will be explained in more detail.

Referring now to FIG. 11, in a first preferred embodiment of the present invention, the first liquid-crystal display 214 has on its two areal sides a polarization filter 210, 212. The efficiency of the front polarization filters 210, 212 is at least 40% and preferably 50%. The thickness of the polarization filters 210, 212 is between 100 μm and 350 μm. One of the two polarization filters 210, 212, preferably the polarization filter 212 which is second in the trans illumination direction 54, furthermore has a retardation element 230 which preferably consists of a film-type material. The thickness of the retardation element 230, which is also referred to as a propagation time film, is preferably between 5 μm and 500 μm. The propagation time difference of the retardation element 230 is preferably λ/4.

The second liquid-crystal layer of this first preferred embodiment is separated by an air gap 250, which is preferably between 1 μm and 10,000 μm. The second liquid-crystal image layer has only at the end of the trans-illumination direction 54 a polarization filter 222, which is likewise provided with a retardation element 260. The thickness of the polarization filters 222 is between 100 μm and 350 μm. The propagation time difference of the circular polarization filter 260 complies with the retardation function f(x) and has the resulting wavelength λ/x₁. The denominator x₁ should be dimensioned such that the propagation time difference of all optical layers is either equal to 0 or corresponds to a multiple n of λ. The thickness of the two liquid-crystal layers is in each case between 600 μm and 2500 μm. The entire multilayer image display device of this embodiment thus comprises three polarization filters 210, 212, 222, two displays and two retardation elements 230 and 260. The thickness of the entire arrangement is between 1505 μm and 17,050 μm.

In a second preferred embodiment of the present invention, the first liquid-crystal display has the same setup as in the first exemplary embodiment. The second liquid-crystal display now has on both its areal sides in each case one polarization filter 220 and one retardation element 221. The first retardation element 221 in the trans-illumination direction 54 has a propagation time difference of λ/4, and the second retardation element has a propagation time difference of λ/x₂. The denominator x₂ should be dimensioned here such that the propagation time difference of all optical layers is either equal to 0 or corresponds to a multiple n of λ.

In a third preferred embodiment of the present invention, the first liquid-crystal display has on its two areal sides a polarization filter 210, 212. Arranged between the first and the second liquid-crystal display is a retardation layer 230, which has a retardation or difference of λ/2. The second liquid-crystal display has, on its two areal sides, a polarization filter 220, 222, and on the side facing away from the first liquid-crystal display a retardation element 260 having a propagation time difference of λ/x₃. The denominator x₃ should be dimensioned here such that the compensation of all optical layers is either equal to 0 or corresponds to a multiple n of λ.

In a fourth preferred embodiment of the present invention, the first liquid-crystal display has, on its two areal sides, a polarization filter. Arranged between the first and the second liquid-crystal display is a retardation layer having a retardation or difference of λ/2. The second liquid-crystal display has, merely on the side facing away from the first liquid-crystal display, a polarization filter having a retardation element and propagation time difference of λ/x₄. The denominator x₄ should be dimensioned here such that the compensation of all optical layers is either equal to 0 or corresponds to a multiple n of λ.

The frequency domain for the linear polarization filter 210, 212, 220, 222 and circular polarization filters 212, 230; 220, 221; 222, 260 is in each case between 400 and 700 μm.

The different possible combinations of the above four preferred embodiments are summarized in the following table. The uppermost row gives the reference numbers of the individual layers 1 to 4. Row 2 reads for example as follows: a polarization filter 210 is used next to the liquid-crystal layer 214. On the other side of the liquid-crystal layer 214, a polarization filter 212 and a retardation element 230 follow. After the air gap 250, another polarization filter 220 having a retardation element 221 follows. Finally, the liquid-crystal layer 224 is followed by a polarization filter 222 having a retardation element 260.

Row 5 contains the respective thicknesses of the individual layers in μm.

| | 210 | 214 | 212 | 230 | 250 | 220 | 221 | 224 | 222 | 260 |
|---|---|---|---|---|---|---|---|---|---|---|
| 1 | pol. | LCD | pol. | λ/4 | air | ./. | ./. | LCD | pol. | λ/x₁ |
| 2 | pol. | LCD | pol. | λ/4 | air | pol. | λ/4 | LCD | pol. | λ/x₂ |
| 3 | pol. | LCD | pol. | λ/2 | air | pol. | ./. | LCD | pol. | λ/x₃ |
| 4 | pol. | LCD | pol. | λ/2 | air | ./. | ./. | LCD | pol. | λ/x₄ |
| Thickness | 100-350 | 600-2500 | 100-350 | 5-500 | 0-1000 | 100-350 | 5-500 | 600-2500 | 100-350 | 0-500 |
| [μm] | | | | | | | | | | |

The following is a summary list of reference numerals and the corresponding structure used in the above description of the invention:

### LIST OF REFERENCE SIGNS

2 image display device
4 rear liquid-crystal display
6 front liquid-crystal display
8 observer
10 rear polarization filter
12 front polarization filter
14 liquid crystal
16 light source
18 electrode
20, 20′ rear polarization filter
22, 22′ front polarization filter
24 liquid crystal
26 depolarization filter
28 electrode
30 interface
32 interface
34 rear side
36 rear side
38 front side
40 front side
42 mirroring unit
44 image center line
46 image computer
48 background image
50 foreground image
52 interface
54 longitudinal extent direction
60 reflective polarizer
70 LCD display
72 interface
74 image computer
76 corrector module
102 image display device
104 observer
106, 106′ front display
108 rear display
110 light source
112 image computer
210 polarization filter
212 polarization filter
214 liquid-crystal layer
220 polarization filter
221 retardation element
222 polarization filter
224 liquid-crystal layer
230 retardation element
250 gas (air)
260 retardation element
d distance
A axis
B axis
U cell voltage
V cell voltage

1. A multilayer image display device, comprising:
a component configuration disposed along a longitudinal extent direction from a rear toward a front, said component configuration including and in an order from the rear toward the front:
a light source outputting a light;
a first liquid-crystal layer; and
a second liquid-crystal layer;
at least one first polarization filter assigned to said first liquid-crystal layer;
at least one second polarization filter assigned to said second liquid-crystal layer; and
at least one optical and/or electro-optical retardation element, wherein the light from said light source being guided through said at least one optical and/or electro-optical retardation element before the light reaches an observer.

2. The multilayer image display device according to claim 1, wherein said at least one optical and/or electro-optical retardation element is assigned to said at least one second polarization filter.

3. The multilayer image display device according to claim 2, wherein said at least one optical and/or electro-optical retardation element includes an areal, dimensionally stable and transparent element.

4. The multilayer image display device according to claim 2, wherein said at least one optical and/or electro-optical retardation element includes a signal-processing electronic component.

5. The multilayer image display device according to claim 2, wherein said at least one optical and/or electro-optical retardation element includes an electronic controller which makes possible a propagation time difference or propagation time retardation.

6. The multilayer image display device according to claim 1,
wherein said at least one first polarization filter and said first liquid-crystal layer form a first liquid crystal display;
wherein said at least one second polarization filter and said second liquid-crystal layer form a second liquid crystal display; and
further comprising an air layer disposed between said first and second liquid-crystal displays.

7. The multilayer image display device according to claim 6, wherein said air layer is between 1 and 10,000 μm.

8. The multilayer image display device according to claim 1, wherein said at least one optical and/or electro-optical retardation element satisfies a retardation function f(x).

9. The multilayer image display device according to claim 8, wherein said at least one optical and/or electro-optical retardation function f(x) satisfies a necessary condition that a propagation time difference is either equal to 0 or corresponds to a multiple n of wavelength λ.

10. The multilayer image display device according to claim 1,
wherein said at least one first polarization filter and said first liquid-crystal layer form a first liquid crystal display;
wherein said at least one second polarization filter and said second liquid-crystal layer form a second liquid crystal display;
wherein said component configuration is configured such that a background image generated by said first liquid-crystal display is visible through said second liquid-crystal display from said front;
wherein said second liquid-crystal display is configured on a drive side for representation of an image which, upon observation, is correctly reproduced from its side which is at the rear in an installation position; and
further comprising a mirroring unit mirroring a foreground image to be represented at an image center line, said mirroring unit is connected upstream of said second liquid-crystal display on the drive side for representation of the foreground image which is correctly reproduced upon observation from the front side.

11. The multilayer image display device according to claim 1,
wherein said at least one first polarization filter and said first liquid-crystal layer form a first liquid crystal display;
wherein said at least one second polarization filter and said second liquid-crystal layer form a second liquid crystal display;
wherein said component configuration is configured such that a background image generated by said first liquid-crystal display is visible through said second liquid-crystal display from the front;
wherein at least one of said first and second liquid-crystal displays is optimized in terms of hardware as regards color, brightness and/or contrast for an observation under an inclination angle which differs from zero with respect to a perpendicular on a display surface; and
further comprising a corrector module connected upstream of said first or second liquid-crystal display on a drive side, said corrector module manipulates an image to be represented prior to transmission to said liquid-crystal display by means of digital image processing such that color, brightness and/or contrast are optimized upon observation of said liquid-crystal display from a perpendicular direction.

12. The multilayer image display device according to claim 1, wherein:
said at least one first polarization filter and said first liquid-crystal layer form a first liquid crystal display; and
said at least one second polarization filter and said second liquid-crystal layer form a second liquid crystal display, wherein no depolarization filter is present between said first liquid-crystal display and said second liquid-crystal display.

13. The multilayer image display device according to claim 1, further comprising:
a first liquid-crystal display formed of said at least one first polarization filter being a first rear polarization filter, said first liquid-crystal layer being an interposed matrix of liquid crystals, and a first front polarization filter; and
a second liquid-crystal display formed of said at least one second polarization filter being a second front polarization filter and, behind said second front polarization filter said second liquid-crystal layer being a matrix of liquid crystals, and said second front polarization filter of said second liquid-crystal display is disposed such that it is rotated in terms of its polarization plane through 90° with respect to said first front polarization filter of said first liquid-crystal display.

14. The multilayer image display device according to claim 13, wherein said first rear polarization filter of said first liquid-crystal display is disposed such that it is rotated in terms of its polarization plane through 90° with respect to said first front polarization filter of said first liquid-crystal display.

15. The multilayer image display device according to claim 13, wherein said second liquid-crystal display has a second rear polarization filter which is aligned, in terms of its polarization plane, equal to said first front polarization filter of said first liquid-crystal display.

16. A method for operating a multilayer image display device containing a first liquid-crystal display having a first rear polarization filter, an interposed matrix of liquid crystals, and a first front polarization filter and a second liquid-crystal display having a second front polarization filter and behind the second front polarization filter, a matrix of liquid crystals, which comprises the steps of:
generating a foreground image to be represented on the second liquid-crystal display in a positionally correct manner by an associated image computer, being mirrored at an image center line and reproduced in a mirror-inverted manner on the second liquid-crystal display; and
reproducing a background image without such mirroring on the first liquid-crystal display.

17. A method for operating a multilayer image display device containing a first liquid-crystal display having a first rear polarization filter, an interposed matrix of liquid crystals, and a first front polarization filter and a second liquid-crystal display having a second front polarization filter and behind the second front polarization filter, a matrix of liquid crystals, which comprises the steps of:
subjecting an image to be represented on the liquid-crystal displays, using digital image processing, to a preprocessing operation which is of a nature such that a shift of color, brightness and/or contrast resulting from image reproduction and observation from a specific viewing direction is compensated for.

18. A multilayer image display device, comprising:
a configuration having a rear display and at least one front display, said configuration configured such that an image generated by said rear display is visible through said front display, said at least one front display is an emissive display.

19. The multilayer image display device according to claim 18, wherein said at least one front display is an organic light-emitting diode (OLED) display.

20. The multilayer image display device according to claim 18, wherein said rear display is a non-emissive display through which a light source disposed behind said rear display shines light during operation.

21. The multilayer image display device according to claim 18, wherein said rear display is selected from the group consisting of an LCD display, an emissive display, an organic light-emitting diode (OLED) display, a plasma display and an electroluminescent display.
